(19) United States
(12) Patent Application Publication
(10) Pub. No.: US 2010/0271010 A1
(43) Pub. Date: Oct. 28, 2010

(54) Tool Sensor, System and Method

(75) Inventors: John K. Stevens, Stratham, NH (US); Paul Waterhouse, Selkirk (CA)

Correspondence Address: Larson & Anderson, LLC, re:VAI, P.O. Box 4928, Dillon, CO, 80435-4928, US

(73) Assignee: VISIBLE ASSETS, INC, Mississauga (CA)

(21) Appl. No.: 12/768,582

(22) Filed: Apr. 27, 2010

Related U.S. Application Data
(60) Provisional application No. 61/172,984, filed on Apr. 27, 2009.

(51) Int. Cl. H01L 43/06

(52) U.S. Cl. 324/207.2

(57) ABSTRACT

A tool sensor detects the presence of a tool and optionally identifies that tool as the correct tool for placement in the sensor. The tool sensor may be in the form of a pad, with openings sized to fit the tool, and may have designated locations for a plurality of tools, in which each tool is identified as being the correct tool for its location on or in the sensor.

### CROSS-REFERENCED TO RELATED APPLICATIONS

This application claims the benefit of U.S. provisional application No. 61/172,984 filed Apr. 27, 2009, which application is incorporated herein by reference in its entirety.

This application is related to U.S. patent application Ser. No. 12/390,491 filed Feb. 22, 2009, and to U.S. patent application Ser. No. 12/393,279 filed Feb. 26, 2009, which applications are incorporated herein by reference.

### BACKGROUND OF THE INVENTION

Misplaced tools can lead to substantial expenses in a variety of different ways. For a construction worker, lost tools can be a substantial expense to replace. For a doctor, misplaced tools that may be left in a patient at the end of a surgical procedure can give rise to even greater risks and costs. In industries such as aircraft maintenance, to aircraft maintenance, the missing tool may cause foreign object destruction (FOD), for example to an engine, if it is not detected in a timely manner.

This application relates to tool sensors and systems, and to methods of using such tools sensors and systems, to monitor and keep track of tools. Such systems can be used on construction sites, in operating rooms and any other place where a plurality of tools may be used. The purpose of the invention is to ensure that all of the tools are accounted for, whether it is before leaving a construction site for the night, or closing a patient following surgery.

The identification of tools with antennas and tags operating at different frequencies has been described in the art. For example, commonly assigned US Patent Publication No. 2008/0275530 describes a surgical implant, or a tool such as a wrench in which an antenna is wrapped around the metal body of the implant or tool to allow communication with an RFID device, despite interference or detuning from the implant or tool. Commonly assigned US Patent Publication No. 2009/0160620 also describes combinations of tools with sensor tags.

### SUMMARY OF THE INVENTION

The present application provides a tool sensor that detects the presence of a tool and optionally identifies that tool as the correct tool for placement in the sensor. In some embodiments, the tool sensor is in the form of a pad, with openings sized to fit the tool. In some embodiments, the tools sensor has designated locations for a plurality of tools, in which each tool is identified as being the correct tool for its location on or in the sensor.

### BRIEF DESCRIPTION OF THE DRAWINGS

FIG. 1A and FIG. 1B show a top view and side view of the placement of a permanent magnet near a magnetic reed switch, according to an embodiment of the present invention.

FIG. 2A and FIG. 2B show the use of the magnetic reed switch with a steel tool, according to an embodiment of the present invention.

FIG. 3 is a simplified block diagram of a simple serial pad with LEDs, according to an embodiment of the present invention.

FIG. 4 is a simplified illustration of a smart pad with tag, according to an embodiment of the present invention.

FIG. 5 is simplified illustration of pad cutouts with embedded sensors, according to an embodiment of the present invention.

FIG. 6 shows a further embodiment of a tool sensor of the present invention.

FIG. 7 shows a signature profile for a tool sensor in the absence of a tool obtained using an embodiment of the present invention as in FIG. 6

FIG. 8A shows the tool sensor of FIG. 6 with a wrench in the sensor. FIG. 8B shows the signature profile for this tool sensor when the wrench is in the sensor.

FIG. 9 shows a simple VCO coil detector according to an embodiment of the present invention.

FIG. 10 shows a placement of smart VCO detector units in a Smart Tool Pad, according to an embodiment of the present invention.

FIG. 11 shows an example circuit of a smart VCO detector, according to an embodiment of the present invention.

FIGS. 12A and 12B show an illustration of a smart VCO tool detector in communication with an optional smart tools tag, according to an embodiment of the present invention.

### DETAILED DESCRIPTION OF THE INVENTION

The present applications relates to a tool sensor, a tool sensor system, and a related method.

As used in the present application, including the claims, the term “tool sensor” refers to an apparatus for detecting the presence of a tool in a defined location and for indicating the presence or absence of a tool to a human observer. In some embodiments, the tool sensor may confirm that the tool in the defined location is the “correct” tool for that location.

As used in the present application, including the claims, the term “tool sensor system: refers to an apparatus that includes a plurality of tool sensors for detecting a plurality or set of tools. In this case, indications relevant to the presence or absence of individual tools may be provided, or the tool sensor system may indicate only to completeness or incompleteness of the set of tools, or the tool sensor system may provide indications of both types.

The tool sensor of the invention comprises a detector element whose behavior is dependent the disturbance of an electromagnetic field as a result of a tool being placed in a correct location relative to the tool sensor. In some embodiments, the tool sensor includes a detector whose behavior depend on the presence or strength of a magnetic field, and a magnetic element disposed at a first distance from the detector element. The first distance is selected such that in the absence of a tool, the detector element acts as if no magnetic field, or only a low magnetic field were present. When the intended tool containing ferrous, aluminum, steel or other electrically conductive components is introduced into the space between the detector and the magnetic element, the magnetic field at the detector increases such that the detector behaves in a manner that allows an indication that the toll is present to occur. In other embodiments, the detector comprises a coil that is part of an RC circuit that is detuned as a consequence of a metallic tool being placed adjacent to the coil.

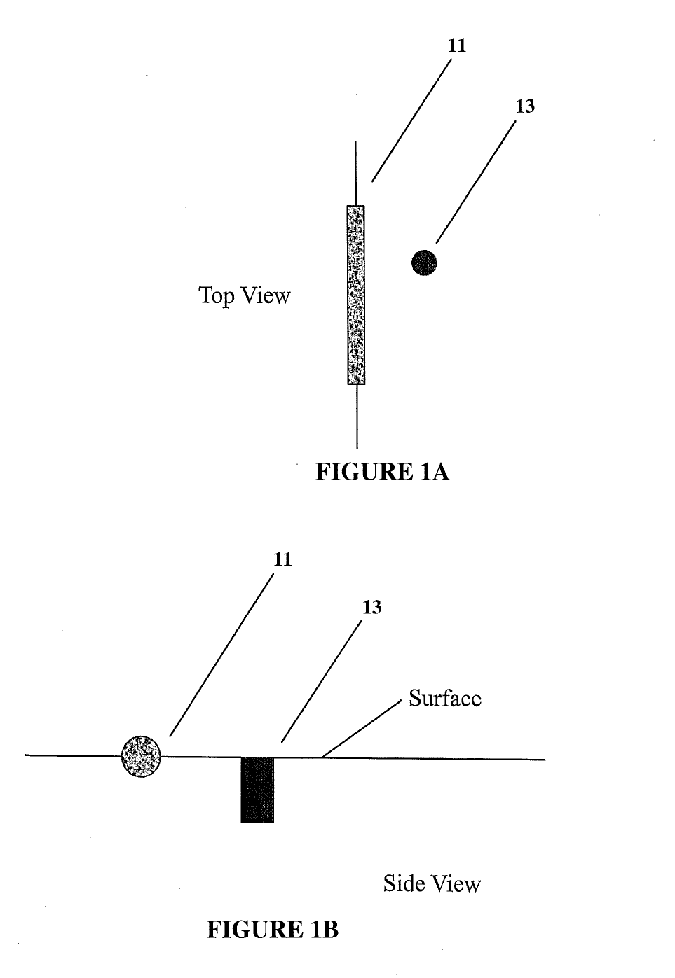

FIG. 1A shows a top view of a first embodiment of a tool sensor in accordance with the invention. FIG. 1B shows a side view of this same embodiment. In FIGS. 1A and B, a magnetic reed switch 11 is placed adjacent to a permanent magnet 13. A reed switch is an electrical switch operated by an applied magnetic field. The switch has a pair of contacts on ferrous metal reeds in a hermetically sealed glass envelope. The contacts are normally open, and close when a magnetic field is present to draw them together. The permanent magnet in FIGS. 1A and 1B is too far from the switch to close the switch.

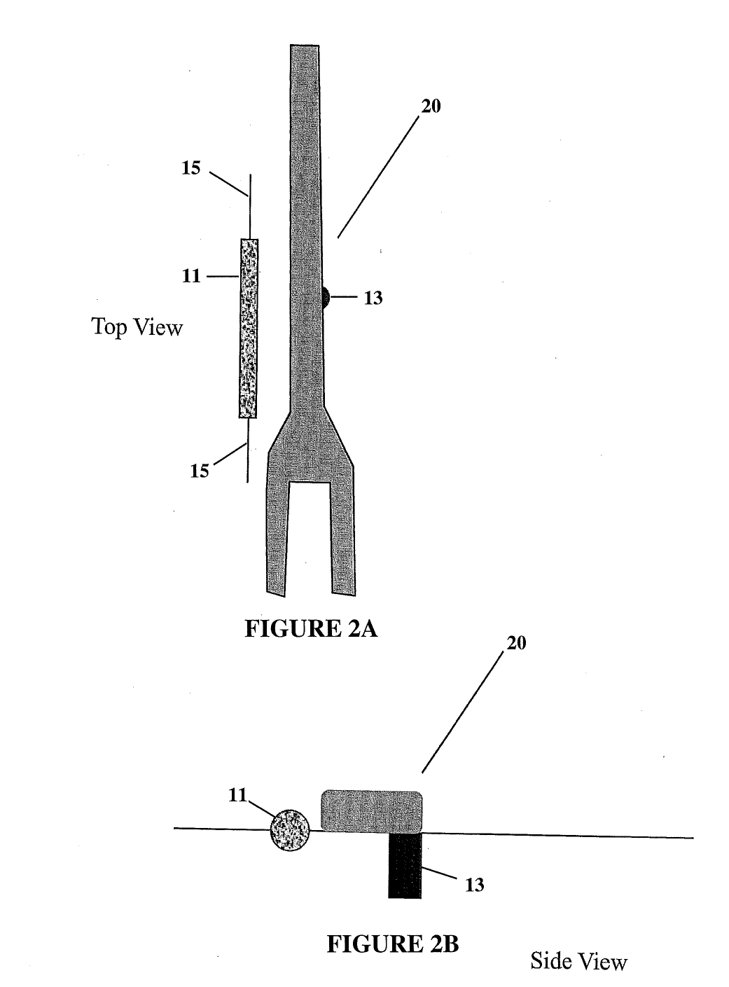

FIGS. 2A and 2B show the same two views with a tool 20 present at the desired location relative to the sensor. The tool acts to bring the magnetic field closer to the reed switch 11, with the result that the reed switch closes. This closes a circuit into which the reed switch 11 is connected via leads 15 and 15′. As a consequence, an indication can be generated that a tool is present in the location required by the sensor.

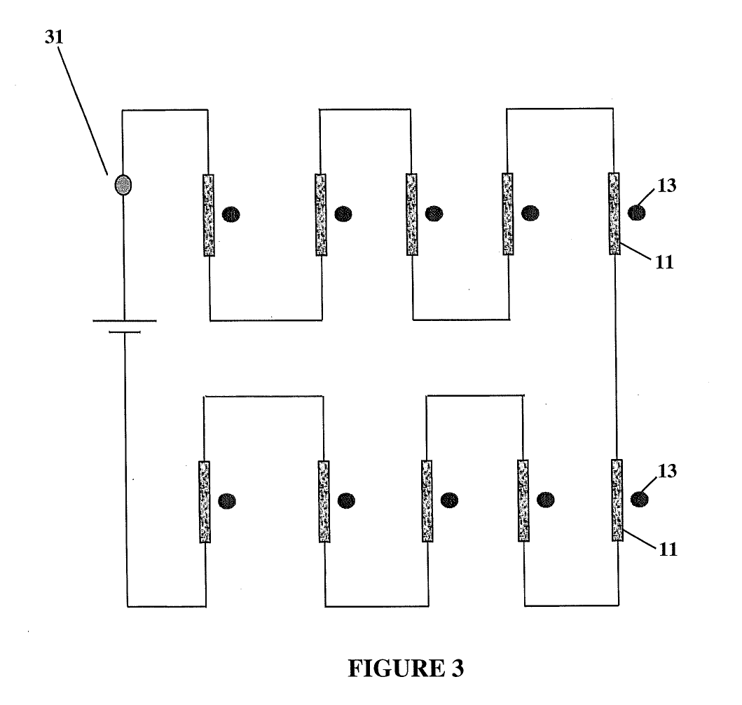

FIG. 3 shows a tool sensor system which incorporates a plurality of tool sensors (in FIG. 3, 10 tool sensors) of the type shown in FIGS. 1 and 2 arranged in a serial circuit with an LED 31. When tools are placed in the correct position relative to each of the tool sensors, all of the reed switches 11 are closed, and the LED 31 will light.

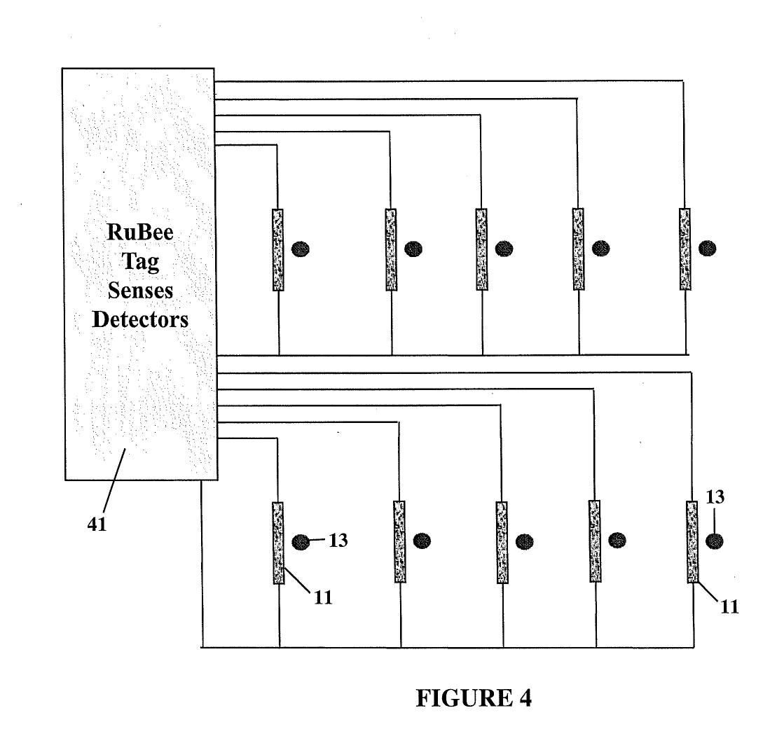

FIG. 4 shows an embodiment of the invention in which the plurality of tool sensors are arranged in parallel such that the presence of a tool at any of the locations can be detected. Such a system could be used with a plurality of LEDs to show the presence of each tool individually. Alternatively, reed switches of the type that is open in the presence of a magnetic field could be used, in which case a single LED that was off would indicate the presence of all of the tools. FIG. 4, however, illustrates the connection of the tool sensor system to a RuBee® tag 41 that senses the status of the individual tools sensors.

Radio tags communicate via magnetic (inductive communication) or electric radio communication to a base station or reader, or to another radio tag. A RuBee® radio tag works through water and other bodily fluids, and near steel, with an eight to fifteen foot range, a five to ten-year battery life, and three million reads/writes. It operates at 132 Khz and is a full on-demand peer-to-peer, radiating transceiver.

RuBee® is a bidirectional, on-demand, peer-to-peer transceiver protocol operating at wavelengths below 450 Khz (low frequency). A transceiver is a radiating radio tag that actively receives digital data and actively transmits data by providing power to an antenna. A transceiver may be active or passive. The RuBee® standard is documented in the IEEE Standards body as IEEE P1902.1™.

Low frequency (LF), active radiating transceiver tags are especially useful for visibility and for tracking both inanimate and animate objects with large area loop antennas over other more expensive active radiating transponder high frequency (HF)/ultra high frequency (UHF) tags. These LF tags function well in harsh environments, near water and steel, and may have full two-way digital communications protocol, digital static memory and optional processing ability, sensors with memory, and ranges of up to 100 feet. The active radiating transceiver tags can be far less costly than other active transceiver tags (many under one dollar), and often less costly than passive back-scattered transponder RFID tags, especially those that require memory and make use of EEPROM. With an optional on-board crystal, these low frequency radiating transceiver tags also provide a high level of security by providing a date-time stamp, making full AES (Advanced Encryption Standard) encryption and one-time pad ciphers possible.

One of the advantages of the RuBee® tags is that they can transmit well through water and near steel. This is because RuBee® operates at a low frequency. Low frequency radio tags are immune to nulls often found near steel and liquids, as in high frequency and ultra high-frequency tags. This makes them ideally suited for use with tools made of steel and/or tools stored near steel shelving. Fluids have also posed significant problems for current tags. The RuBee® tag works well through water. In fact, tests have shown that the RuBee® tags work well even when fully submerged in water. This is not true for any frequency above 1 MHz. Radio signals in the 13.56 MHz range have losses of over 50% in signal strength as a result of water, and anything over 30 MHz have losses of 99%.

Another advantage is that RuBee® tags can be networked. One tag is operable to send and receive radio signals from another tag within the network or to a reader. The reader itself is operable to receive signals from all of the tags within the network. These networks operate at long-wavelengths and accommodate low-cost radio tags at ranges to 100 feet. The standard, IEEE P1902.1™, “RuBee Standard for Long Wavelength Network Protocol”, will allow for networks encompassing thousands of radio tags operating below 450 kHz.

The inductive mode of the RuBee® tag uses low frequencies, 3-30 kHz VLF or the Myriametric frequency range, 30-300 kHz LF in the Kilometric range, with some in the 300-3000 kHz MF or Hectometric range (usually under 450 kHz). In some embodiments, the tag operates at a frequency of 132 kHz. Since the wavelength is so long at these low frequencies, over 99% of the radiated energy is magnetic, as opposed to a radiated electric field. Because most of the energy is magnetic, antennas are significantly (10 to 1000 times) smaller than ¼ wavelength or 1/10 wavelength, which would be required to efficiently radiate an electrical field. This is the preferred mode.

As opposed to the inductive radiation mode above, the electromagnetic mode uses frequencies above 3000 kHz in the Hectometric range, typically 8-900 MHz, where the majority of the radiated energy generated or detected may come from the electric field, and a ¼ or 1/10 wavelength antenna or design is often possible and utilized. The majority of radiated and detected energy is an electric field.

RuBee® tags are also programmable, unlike conventional RFID tags. The RuBee® tags may be programmed with additional data and processing capabilities to allow them to respond to sensor-detected events and to other tags within a network. This programmability allows the RuBee® tag of FIG. 4 to process the information received from the tool sensors in the connected tool sensor system and display or transmit and indication of the information received, i.e. all tools present, all tools absent, some tools present etc.

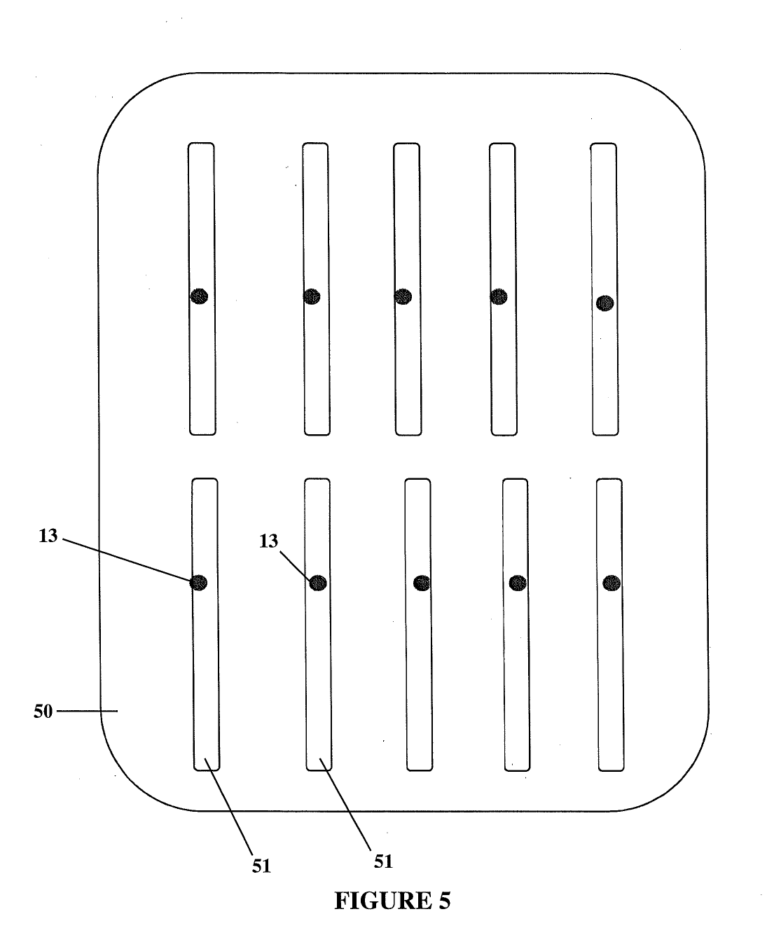

FIG. 5 shows a top view of a pad 50, for example a foam pad, which could be placed over the tool sensor of FIG. 4. The sensor has a cutout 51 for each tool sensor in the tool sensor system. The cutouts 51 define wells into which the tools are to be placed, and they may shaped to accommodate specific tools for each location. The relatively durable permanent magnet 13 shows through the cutouts, but the switches 11 and the RuBee® tag are covered to provide them with greater protection.

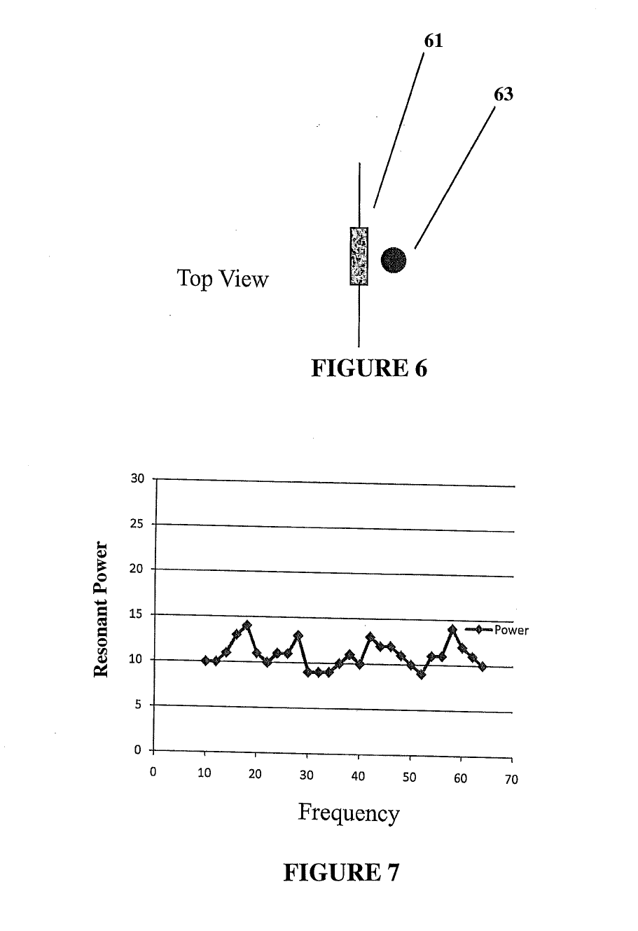

FIG. 6 shows a different embodiment of a tool sensor of the invention. In this case, the detector 61 is a Hall effect detector or a coil detector, and the magnetic element is a variable frequency electromagnet 63. Resonant power at the coil is measured as a function of frequency of the electromagnet. FIG. 7 shows an example of output in the absence of a tool in the tool sensor.

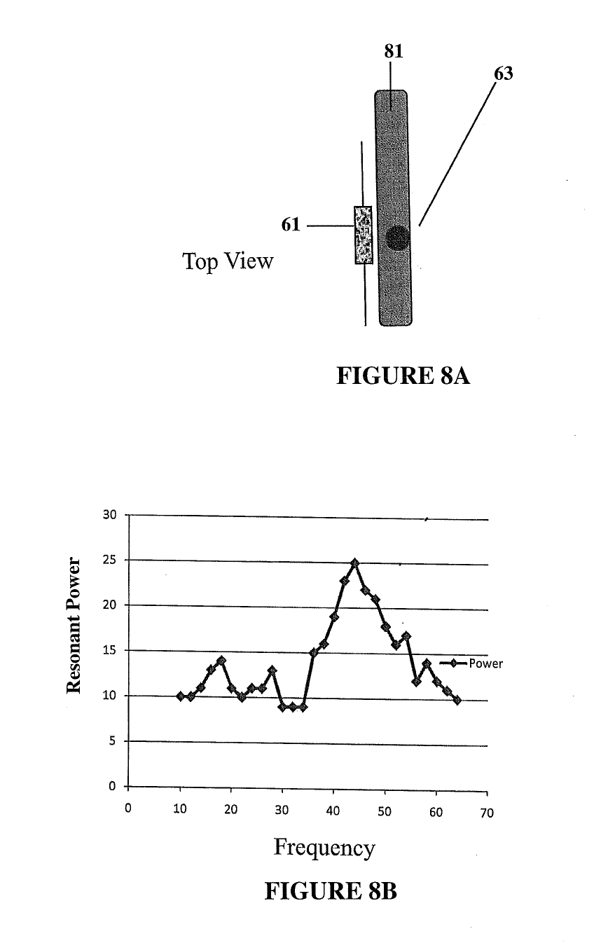

FIG. 8A shows the tool sensor of FIG. 6 with a wrench 81 disposed in the tool sensor. FIG. 8B shows the output in the presence of wrench in the tool sensor. As can be seen, this is significantly different from output in the absence of the wrench. Moreover, the output provides a signature profile of the wrench which allows it to be distinguished from tools of a different size or type.

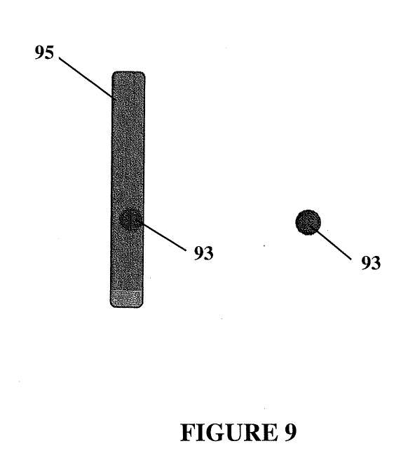

FIG. 9 shows a tool sensor of the invention in which a voltage-controlled oscillator (VCO) coil 93 that is part of an RC circuit is detuned by the presence of a metallic tool 95 disposed adjacent part of the coil 93.

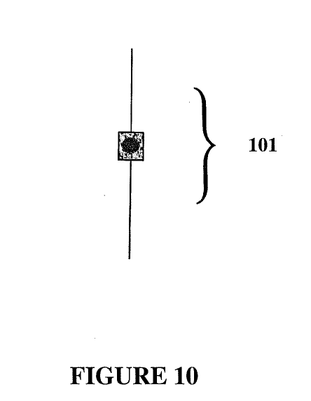

FIG. 10 shows a VCO detector unit 101 formed from a VCO detector tool sensor such as that of FIG. 9. The VCO detector units also include a microcontroller unit (MCU) with a unique identifier and a VCO circuit that identifies tool presence and optionally the size of the tool. The ability to detect the size of the tool arises because the extent to which the VCO is detuned by the presence of the tool is related to the size of the tool. To determine the extent of detuning, the voltage can be adjusted to retune the VCO to the original oscillator frequency. The amount of voltage change is related to the size of the tool. In the alternative, the new frequency of the VCO can be determined, and the frequency change is related to the size of the tool.

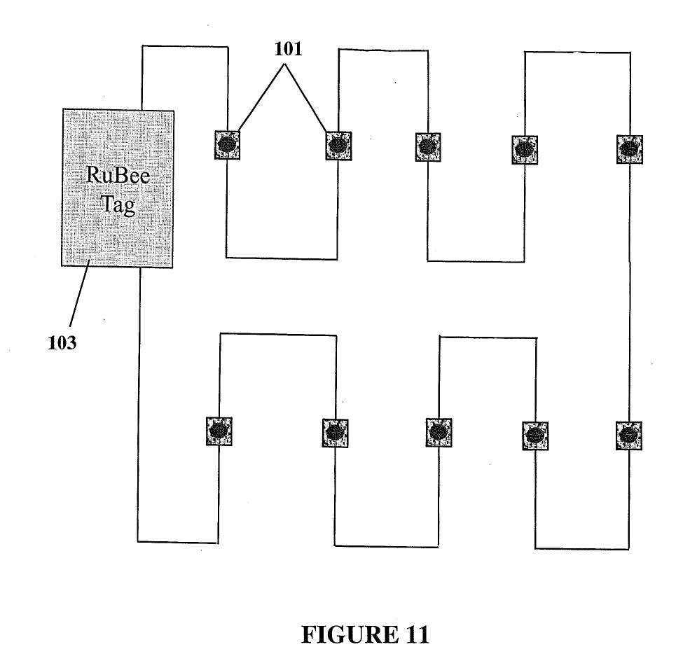

FIG. 11 shows a tool sensor system with a serial arrangement of VCO detector units 101 connected to a single wire bus. A single RuBee® tag 103 is connected to the tool sensor bus to transmit status of the tool pad.

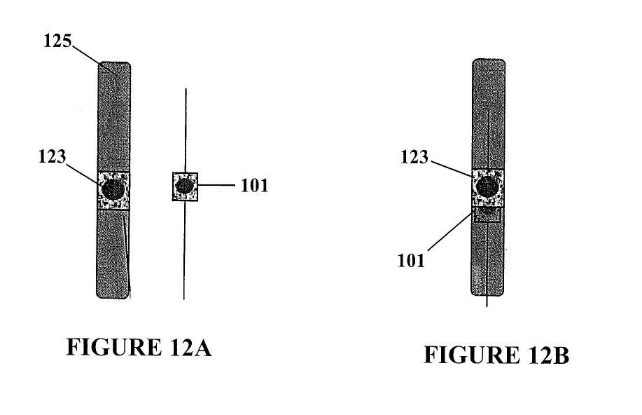

As depicted in FIG. 12, VCO detector unit of FIG. 10 can be configured to communicate with a tool tag 123, for example a RuBee® tag, embedded within or attached to the tool 125 as described in U.S. patent application Ser. No. 12/393,279 referenced above. The tool tag 123 in this case has a coil tuned to the coil of the VCO detector such that communication is enabled only when the tool and the detector are in the desired arrangement, for example, coplanar. The VCO detector coil can provide power to the tool tag, and provides for full and explicit identification of the particular tool and verification that the correct tool is in place.

The tool sensors, individually or as part of a tool sensor system are used to monitor the presence of a tool in a defined tool location. Thus, the present application also provides a method for monitoring the presence of a tool in a defined location comprising the step of:
defining the tool location using a tool sensor, wherein the tool sensor comprises a detector element and a tool holder that defines a location for a tool relative to the detector element, wherein the detector element provides signal dependent on a disturbance in an electromagnetic field as a result of a tool being placed in the tool holder, and
observing a signal from the tool sensor to determine if a tool is in the defined location. In this method the various embodiments of the tool sensor as described above may be employed.

Thus, the detector element used in the method may comprise a reed switch, and the tool sensor may further comprises a magnet. The reed switch is in a first position when the tool is present in the tool holder and a second position when no tool is present in the tool holder, and the observed signal is different depending on the position of the reed switch. In specific embodiments, the position of the reed switch is reflected in the illumination of a light, such as an LED.

The detector element used in the method may also comprise a Hall Effect coil or a coil detector, in which case the tool sensor suitably also comprises a variable frequency electromagnet. In this case, the observed signal may be the resonant power at the coil as a function of frequency of the electromagnet.

The detector element used in the method may also be a voltage-controlled oscillator (VCO) coil. In this case, the detector element may further comprise a microcontroller unit storing a unique identifier, and a VCO circuit that identifies tool presence and size in the tool holder. In some embodiments, the VCO coil is tuned to a frequency that is the same as the frequency of a low frequency tag associated with the tool for which the tool holder is intended, which can communicate with and power the tag associated with the tool when the tool is properly placed in the tool holder.

In further embodiments, the method may be practiced using a tool sensor that comprises a low frequency transceiver tag that processes the input from the tool sensor and displays or transmits an indication of the presence or absence of tools in the tool holder.

In the foregoing examples, the embodiments describe exemplary combinations of features, but all possible combinations of the features are not specifically set forth. The person skilled in the art will appreciate that the detector types and analysis/indicator systems can be combined in other combinations, or used together, for example to provide multiple indicators such as an LED and a RuBee® tag in the same tool sensor system without departing from the spirit and scope of the invention.

1. A tool sensor comprising a detector element and a tool holder that defines a location for a tool relative to the detector element, wherein the detector element provides signal dependent on a disturbance in an electromagnetic field as a result of a tool being placed in the tool holder.

2. The tool sensor of claim 1, wherein the detector element comprises a reed switch, and wherein the tool sensor further comprises a magnet, wherein the reed switch is in a first position when the tool is present in the tool holder and a second position when no tool is present in the tool holder.

3. The tool sensor of claim 2, wherein the magnet is a permanent magnet.

4. The tool sensor of claim 2, wherein the reed switch is closed when a tool is present in the tool holder, and open when no tool is present in the tool holder.

5. The tool sensor of claim 1, wherein the detector element comprises a Hall Effect coil or a coil detector, and wherein the tool sensor further comprises a variable frequency electromagnet.

6. The tool sensor of claim 1, wherein the detector element comprises a voltage-controlled oscillator (VCO) coil.

7. The tool sensor of claim 6, wherein the sensor further comprises a microcontroller unit, said microcontroller unit storing a unique identifier, and a VCO circuit that identifies tool presence and size in the tool holder.

8. A tool sensor system comprising
a plurality of tool sensors, each tool sensor comprising a detector element and a tool holder that defines a location for a tool relative to the detector element, wherein the detector element provides signal dependent on a disturbance in an electromagnetic field as a result of a tool being placed in the tool holder, and
an indicator device for communicating concerning the number of tools disposed in the tool holders of the tool sensor system.

9. The tool sensor system of claim 8, wherein the tool holders are cutouts in the layer disposed over the detector elements of the tool sensors, said cutouts defining the location for placement of each tool in relation to the tool sensor.

10. The tool sensor system of claim 9, wherein the layer in which the cutouts are formed is a foam pad.

11. The tool sensor system of claim 8, wherein the detector element of each tool sensor comprises a reed switch, and wherein each tool sensor further comprises a magnet, wherein the reed switch is in a first position when the tool is present in the tool holder and a second position when no tool is present in the tool holder.

12. The tool sensor system of claim 11, wherein the indicator is an LED, and wherein the tool sensors are arranged in series such that the LED is lit when a tool is present in each tool holder of the tool sensor system.

13. The tool sensor system of claim 8, wherein the detector element of each tool sensor comprises a Hall Effect coil or a coil detector, and wherein each tool sensor further comprises a variable frequency electromagnet.

14. The tool sensor system of claim 8, wherein the detector element in each tool sensor comprises a voltage-controlled oscillator (VCO) coil.

15. The tool sensor system of claim 14, wherein each detector element further comprises a microcontroller unit, said microcontroller unit storing a unique identifier, and a VCO circuit that identifies tool presence and size in the tool holder.

16. The tool sensor system of claim 8, wherein the indicator comprises a low frequency transceiver tag that processes the input from the tool sensors and displays or transmits an indication of the presence or absence of tools in the tool sensor system

17. The tool sensor system of claim 16, wherein the tool holders are cutouts in the layer disposed over the detector elements of the tool sensors, said cutouts defining the location for placement of each tool in relation to the tool sensor.

18. The tool sensor system of claim 16, wherein the detector element of each tool sensor comprises a Hall Effect coil or a coil detector, and wherein each tool sensor further comprises a variable frequency electromagnet.

19. The tool sensor system of claim 16, wherein the detector element in each tool sensor comprises a voltage-controlled oscillator (VCO) coil.

20. The tool sensor system of claim 19, wherein each detector element further comprises a microcontroller unit, said microcontroller unit storing a unique identifier, and a VCO circuit that identifies tool presence and size in the tool holder.

21. A method of monitoring the presence of a tool in a defined tool location comprising
defining the tool location using a tool sensor, wherein the tool sensor comprises a detector element and a tool holder that defines a location for a tool relative to the detector element, wherein the detector element provides signal dependent on a disturbance in an electromagnetic field as a result of a tool being placed in the tool holder, and
observing a signal from the tool sensor to determine if a tool is in the defined location.

22. The method of claim 21, wherein the detector element comprises a reed switch, and wherein the tool sensor further comprises a magnet, wherein the reed switch is in a first position when the tool is present in the tool holder and a second position when no tool is present in the tool holder, and the observed signal is different depending on the position of the reed switch.

23. The method of claim 22, wherein an LED Is connected to the reed switch and is off or on depending on the position of the reed switch.

24. The method of claim 21, wherein the detector element comprises a Hall Effect coil or a coil detector, and wherein the tool sensor further comprises a variable frequency electromagnet.

25. The method of claim 24, wherein observed signal is resonant power at the coil as a function of frequency of the electromagnet.

26. The method of claim 21, wherein the detector element comprises a voltage-controlled oscillator (VCO) coil.

27. The method of claim 26, wherein the detector element further comprises a microcontroller unit, said microcontroller unit storing a unique identifier, and a VCO circuit that identifies tool presence and size in the tool holder.

28. The method of claim 27, wherein the VCO coil is tuned to a frequency that is the same as the frequency of a low frequency tag associated with the tool for which the tool holder is intended, can communicate with and power the tag associated with the tool when the tool is properly placed in the tool holder.

29. The method of claim 21, wherein the tool sensor further comprises a low frequency transceiver tag that processes the input from the tool sensor and displays or transmits an indication of the presence or absence of tools in the tool holder.
